(19) United States
(12) Patent Application Publication
(10) Pub. No.: US 2018/0182730 A1
(43) Pub. Date: Jun. 28, 2018

(54) COMMON CONTACT SEMICONDUCTOR DEVICE PACKAGE

(71) Applicant: Infineon Technologies Americas Corp., El Segundo, CA (US)

(72) Inventor: Eung San Cho, Torrance, CA (US)

(21) Appl. No.: 15/389,974

(22) Filed: Dec. 23, 2016

(51) Int. Cl. H01L 23/00; H01L 25/07; H01L 27/088; H01L 29/78; H01L 25/065; H01L 25/00; H02P 27/06

(52) U.S. Cl. CPC H01L 24/40; H01L 2224/37011; H01L 27/088; H01L 29/7827; H01L 25/0655; H01L 25/50; H01L 24/84; H02P 27/06; H01L 2224/40137; H01L 2224/40225; H01L 2924/1426; H01L 2924/13081; H01L 2924/13091; H01L 2924/13055; H01L 25/072

(57) ABSTRACT

A semiconductor device package includes a conductive clip that has a recess and that is configured to mount to a substrate along a first surface and a second surface that bound the recess, and that includes at least two vertical channel transistors that are of a same type and that are mounted within the recess in a same orientation such that a drain or source contact is coupled to the conductive clip, and such that a gate contact and a source or drain contact extend exposed within the recess and along a same long axis of the conductive clip.

### BACKGROUND

Surface-mount technology is a production method for electronics that involves attaching passive or active components, such as those realized as a packaged device for example, to a printed circuit board. Such components may be soldered to the printed circuit board to establish connections with other components mounted thereto.

### SUMMARY

The present disclosure relates to a common contact semiconductor device package. The phrase “common contact” is intended to convey that at least two devices that are of a same type are coupled to a portion of the semiconductor device package in a same orientation such that like contacts on a first side of the devices are coupled to the portion of the semiconductor device package, and such that like contacts on a second side of the devices extend exposed and are aligned in a particular orientation.

Thus, according to an aspect of the present disclosure, a semiconductor device package may include or comprise a conductive clip that includes a recess and that is configured to mount to a substrate along a first surface and a second surface that bound the recess, and at least two vertical channel transistors that are of a same type and that are mounted within the recess in a same orientation such that a drain or source contact is coupled to the conductive clip, and such that a gate contact and a source or drain contact extend exposed within the recess and along a same long axis of the conductive clip.

Such an implementation represents a paradigm shift in that, when the semiconductor device package is incorporated in a half-bridge circuit for example, the conductive clip may be utilized as a power supply node for the half-bridge circuit whereas a conductive trace or pad on the substrate may be utilized as a switch node for the half-bridge circuit. Additionally, a manufacturing-related benefit may be realized because the orientation of the vertical channel transistors facilitates registration between the semiconductor device package and a substrate during a process to surface-mount the semiconductor device package to the substrate, and a performance-related benefit may be realized because the semiconductor device package itself does not degrade device level characteristics of the vertical channel transistors.

### BRIEF DESCRIPTION OF DRAWINGS

FIG. 1 shows a schematic block diagram of a half-bridge circuit according to the disclosure.

FIG. 2 shows perspective views of a first semiconductor die according to the disclosure.

FIG. 3 shows perspective views of a second semiconductor die according to the disclosure.

FIG. 4 shows a cross-sectional view of a first common contact semiconductor device package according to the disclosure.

FIG. 5 shows a bottom view of the semiconductor device package of FIG. 4.

FIG. 6 shows a cross-sectional view of a second common contact semiconductor device package according to the disclosure.

FIG. 7 shows a bottom view of the semiconductor device package of FIG. 6.

FIG. 8 shows a bottom view of the half-bridge circuit of FIG. 1 realized using the package of FIGS. 4-5.

FIG. 9 shows a bottom view of the half-bridge circuit of FIG. 1 realized using the package of FIGS. 6-7.

FIG. 10 shows a top view of the half-bridge circuit of FIG. 8 or FIG. 9.

FIG. 11 shows a flowchart of an example method according to the disclosure.

### DETAILED DESCRIPTION

The present disclosure relates to a common contact semiconductor device package. The phrase “common contact” is intended to convey that at least two devices that are of a same type are coupled to a portion of the semiconductor device package in a same orientation such that like contacts on a first side of the devices are coupled to the portion of the semiconductor device package, and such that like contacts on a second side of the devices extend exposed and are aligned in a particular orientation. Thus, according to an aspect of the present disclosure, a semiconductor device package may include or comprise a conductive clip that includes a recess and that is configured to mount to a substrate along a first surface and a second surface that bound the recess, and at least two vertical channel transistors that are of a same type and that are mounted within the recess in a same orientation such that a drain or source contact is coupled to the conductive clip, and such that a gate contact and a source or drain contact extend exposed within the recess and along a same long axis of the conductive clip. Such an implementation represents a paradigm shift in that, when the semiconductor device package is incorporated in a half-bridge circuit for example, the conductive clip may be utilized as a power supply node for the half-bridge circuit whereas a conductive trace or pad on the substrate may be utilized as a switch node for the half-bridge circuit. Although not so limited, an appreciation of the various aspects of the present disclosure may be gained from the following discussion provided in connection with the drawings.

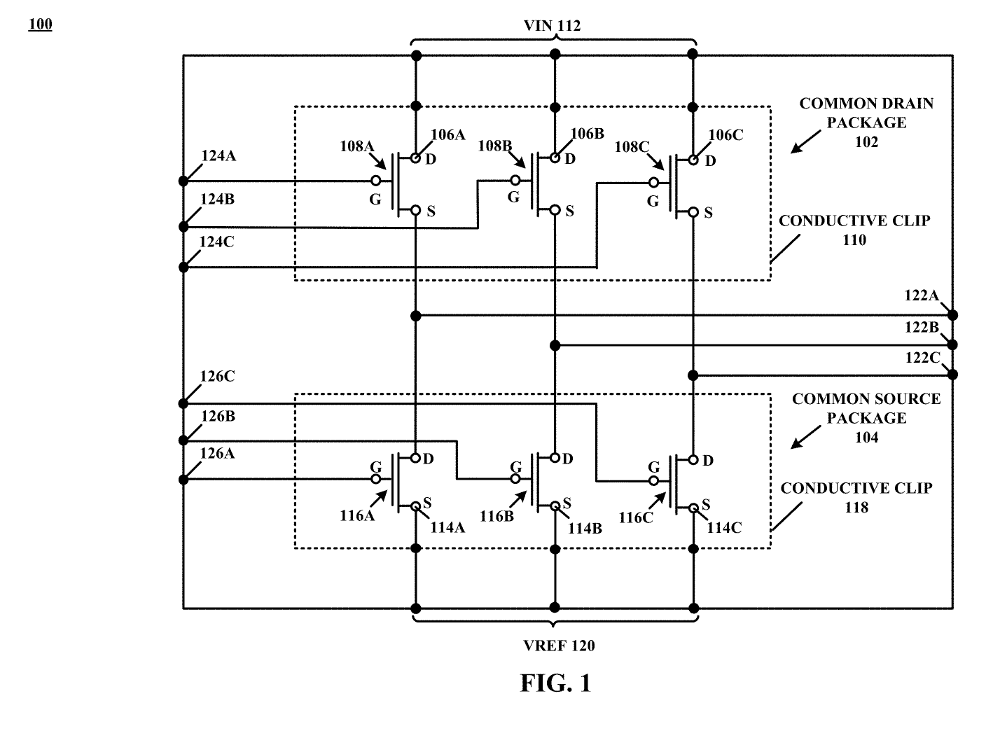

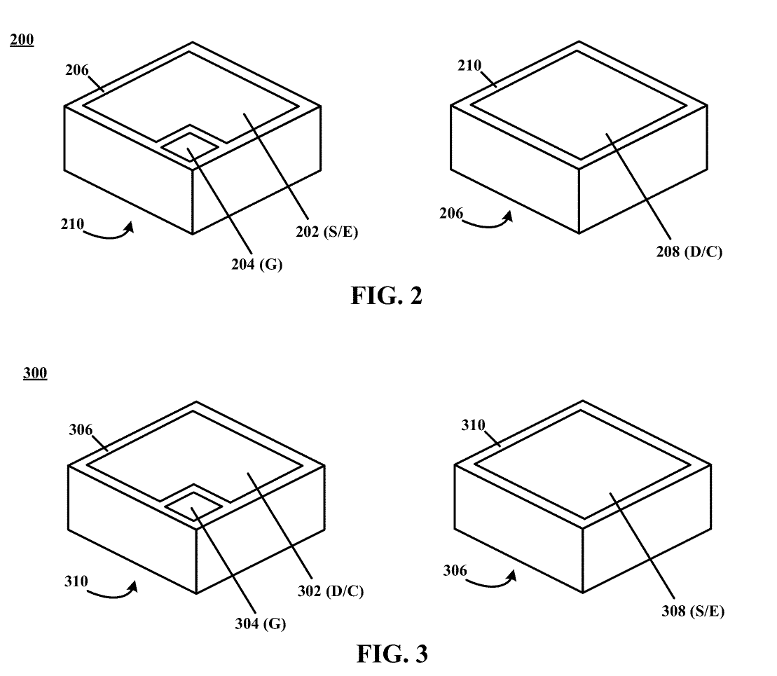

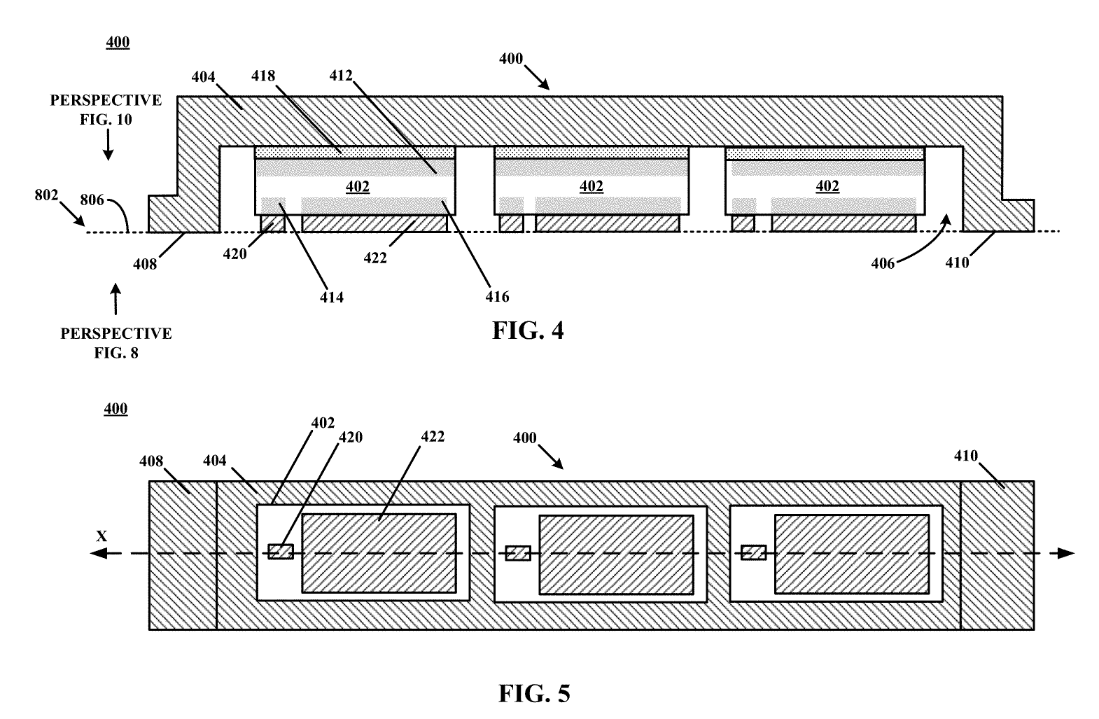

For example, FIG. 1 shows a schematic block diagram of a half-bridge circuit 100 according to the disclosure. In particular, half-bridge circuit 100 includes a first common contact semiconductor device package 102 (hereinafter “first package 102”) and a second common contact semiconductor device package 104 (hereinafter “second package 104”). First package 102 is an example of a common drain semiconductor device package whereby a drain contact 106A-C (collectively “drain contact 106”) of a corresponding one of a plurality of high-side transistors 108A-C (collectively “high-side transistor 108”) is coupled to a conductive clip 110 of first package 102. Conductive clip 110 in turn is coupled to a supply voltage node 112. An example of high-side transistor 108 is illustrated in FIG. 2. An example of conductive clip 110 is illustrated in FIGS. 4-7. In contrast, second package 104 is an example of a common source semiconductor device package, whereby a source contact 114A-C (collectively “source contact 114”) of a corresponding one of a plurality of low-side transistors 116A-C (collectively “low-side transistor 116”) is coupled to a conductive clip 118 of second package 104. Conductive clip 118 in turn is coupled to a reference voltage node 120. An example of low-side transistor 116 is illustrated in FIG. 3. An example of conductive clip 118 is illustrated in FIGS. 4-7.

In the example of FIG. 1, high-side transistor 108A and low-side transistor 116A are connected in cascode arrangement and together define a first half-bridge circuit whereby a source contact of high-side transistor 108A is coupled to a drain contact of low-side transistor 116A to define a first switch node 122A. Additionally, a gate contact of high-side transistor 108A is coupled to a first high-side input node 124A, and a gate contact of low-side transistor 116A is coupled to a first low-side input node 126A. As would be understood by one of skill, a voltage waveform that switches in magnitude between (approximately) voltage level at supply voltage node 112 and voltage level at reference voltage node 120 is developed at first switch node 122A in response to timed signals supplied to the gate contacts of high-side transistor 108A and low-side transistor 116A via first high-side input node 124A and first low-side input node 126A, respectively.

In the example of FIG. 1, high-side transistor 108B and low-side transistor 116B are connected in cascode arrangement and together define a second half-bridge circuit whereby a source contact of high-side transistor 108B is coupled to a drain contact of low-side transistor 116B to define a second switch node 122B. Additionally, a gate contact of high-side transistor 108B is coupled to a second high-side input node 124B, and a gate contact of low-side transistor 116B is coupled to a second low-side input node 126B. As would be understood by one of skill, a square wave voltage waveform that switches in magnitude between (approximately) voltage level at supply voltage node 112 and voltage level at reference voltage node 120 is developed at second switch node 122B in response to timed signals supplied to the gate contacts of high-side transistor 108B and low-side transistor 116B via second high-side input node 124B and second low-side input node 126B, respectively.

In the example of FIG. 1, high-side transistor 108C and low-side transistor 116C are connected in cascode arrangement and together define a third half-bridge circuit whereby a source contact of high-side transistor 108C is coupled to a drain contact of low-side transistor 116C to define a third switch node 122C. Additionally, a gate contact of high-side transistor 108C is coupled to a third high-side input node 124C, and a gate contact of low-side transistor 116C is coupled to a third low-side input node 126C. As would be understood by one of skill, a square wave voltage waveform that switches in magnitude between (approximately) voltage level at supply voltage node 112 and voltage level at reference voltage node 120 is developed at third switch node 122C in response to timed signals supplied to the gate contacts of high-side transistor 108C and low-side transistor 116C via third high-side input node 124C and third low-side input node 126C, respectively.

Thus, although the present disclosure is not so limited, half-bridge circuit 100 of FIG. 1 is an example of a three-phase half-bridge circuit. As an example, a three-phase half-bridge circuit may be utilized in or as part of a three-phase power supply or motor control solution. Thus, it is contemplated that high-side transistor 108 of FIG. 1, and low-side transistor 116 of FIG. 1, may be realized as a multi-terminal power semiconductor device that is a switch and that is of a type that is implementation-specific.

For example, any particular instance of high-side transistor 108, and any particular instance of low-side transistor 116, may be realized as an IGBT (Insulated-Gate Bipolar Transistor) power transistor. Additionally, or alternatively, any particular instance of high-side transistor 108, and any particular instance of low-side transistor 116, may be realized as a vertical n-channel or p-channel MOSFET (Metal-Oxide-Semiconductor Field-Effect Transistor) power transistor. Additionally, or alternatively, any particular instance of high-side transistor 108, and any particular instance of low-side transistor 116, may be realized as a vertical n-channel or p-channel FINFET (Fin Field-Effect Transistor) power transistor, whereby any one of the foregoing types of power transistors are made and sold by Infineon Technologies of Neubiberg, Germany. In these and other examples, any particular instance of high-side transistor 108, and any particular instance of low-side transistor 116, may be formed of or as a semiconductor die.

FIG. 2 shows perspective views of a first semiconductor die 200 according to the disclosure. In particular, FIG. 2 shows a single instance of high-side transistor 108 integrated within or formed as first semiconductor die 200. Although, as discussed below in connection with FIGS. 4-7, more than a single instance of high-side transistor 108 may be integrated within or formed as first semiconductor die 200. In the example of FIG. 2, however, a source (emitter) contact 202 and a gate contact 204 are arranged on a front side 206 of semiconductor die 200, whereas a drain (collector) contact 208 is arranged on a back side 210 of semiconductor die 200. As mentioned above, high-side transistor 108 may correspond to a multi-terminal power semiconductor device that is a switch and that is of a type that is implementation-specific. Thus, during switching of the half-bridge circuit defined by high-side transistor 108 and low-side transistor 116 as discussed above in connection with FIG. 1, current flows between source (emitter) contact 202 and drain (collector) contact 208 in response to an appropriate voltage supplied across source (emitter) contact 202 and drain (collector) contact 208 as well as an appropriate voltage supplied to gate contact 204.

FIG. 3 shows perspective views of a third semiconductor die 300 according to the disclosure. In particular, FIG. 3 shows a single instance of low-side transistor 116 integrated within or formed as third semiconductor die 300. Although, as discussed below in connection with FIGS. 4-7, more than a single instance of low-side transistor 116 may be integrated within or formed as third semiconductor die 300. In the example of FIG. 3, however, a drain (collector) contact 302 and a gate contact 304 are arranged on a front side 306 of second semiconductor die 300, whereas a source (emitter) contact 308 is arranged on a back side 310 of second semiconductor die 300. As mentioned above, low-side transistor 116 may correspond to a multi-terminal power semiconductor device that is a switch and that is of a type that is implementation-specific. Thus, during switching of the half-bridge circuit defined by high-side transistor 108 and low-side transistor 116 as discussed above in connection with FIG. 1, current flows between drain (collector) contact 302 and source (emitter) contact 308 in response to an appropriate voltage supplied across drain (collector) contact 302 and source (emitter) contact 308 as well as an appropriate voltage supplied to gate contact 304.

As mentioned above, a single instance of high-side transistor 108 may be integrated within or formed as first semiconductor die 200, and a single instance of low-side transistor 116 may be integrated within or formed as third semiconductor die 300. FIGS. 4-5 show a first common contact semiconductor device package 400 (hereinafter “package 400”) that comprises a number of distinct instances of semiconductor die 402 coupled to a conductive clip 404 whereby, due to similarity in structural configuration of first semiconductor die 200 of FIG. 2 and second semiconductor die 300 of FIG. 3, semiconductor die 402 may correspond to either one of first semiconductor die 200 and second semiconductor die 300. Similarly, conductive clip 404 may correspond to either one of conductive clip 110 and conductive clip 188 of FIG. 1. By extension, package 400 of FIGS. 4-5 may correspond to either one of first package 102 and second package 104 of FIG. 1. Thus the discussion provided with reference to package 400 of FIGS. 4-5 is equivalently applicable to each one of first package 102 and second package 104 as shown in FIG. 1.

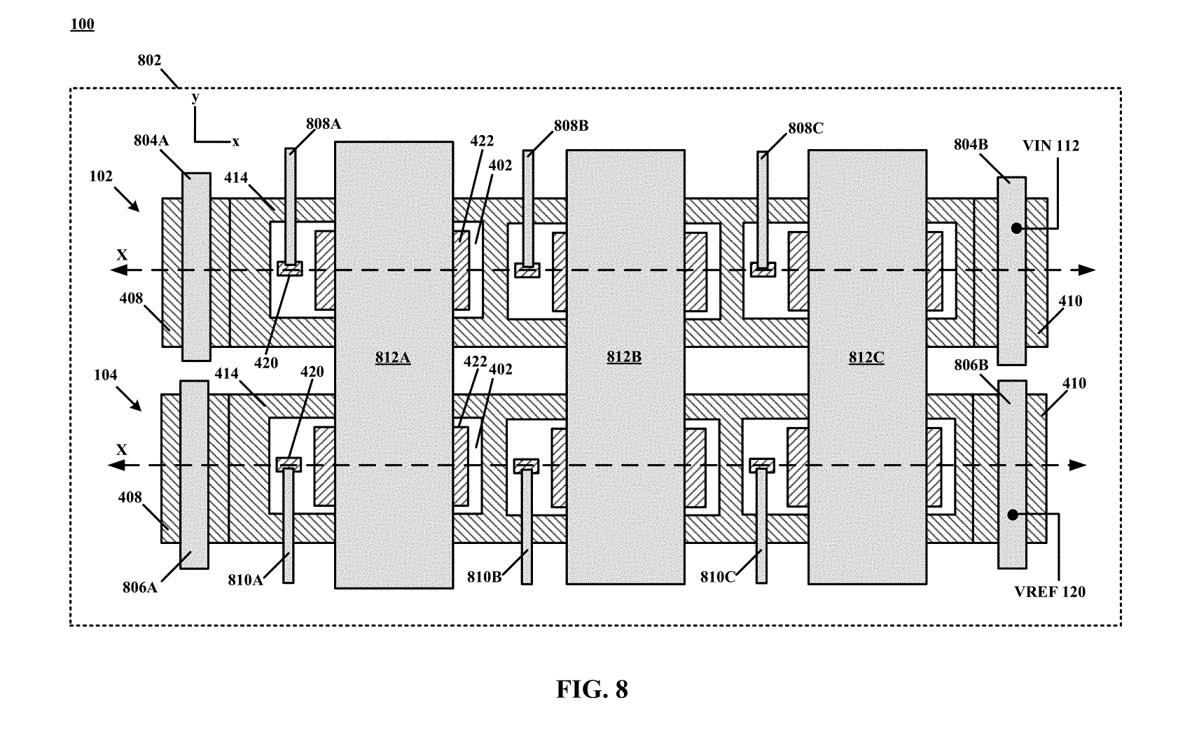

In particular, FIG. 4 shows a cross-sectional view of package 400 according to the disclosure, and FIG. 5 shows a bottom view of package 400 of FIG. 4. Example views of package 400 of FIGS. 4-5 mounted to a substrate 802 is illustrated in at least one of FIGS. 8-10. As mentioned above, package 400 comprises conductive clip 404. Conductive clip 404 includes a recess 406 (see FIG. 4) and is configured to mount to substrate 802 along a first surface 408 and a second surface 410 that bound recess 406. In this example, each one of three instances of semiconductor die 402, illustrated solely to be consistent with the three-phase half-bridge circuit example of the present disclosure, is mounted within recess 406 in a same orientation such that a drain or source contact 412 is coupled to conductive clip 404, and such that a gate contact 414 and a source or drain contact 416 extend exposed within the recess 406 and along a same long axis X of conductive clip 404 (see FIG. 5). In some examples, although not required, a conductive adhesive 418 is in place between drain or source contact 412 and conductive clip 404. In some examples, although not required, a conductive contact 420 is in positioned to gate contact 414 and a conductive contact 422 is in positioned to source or drain contact 416 to facilitate a surface-mounting process whereby package 400 is mounted to substrate 802. Such an implementation as shown in FIGS. 4-5, whereby gate contact 414 and source or drain contact 416 extend exposed within the recess 406 and are aligned along long axis X of conductive clip 404 as shown in FIG. 5, advantageously facilitates precise registration with conductive traces or pads on a substrate (see FIGS. 8-10).

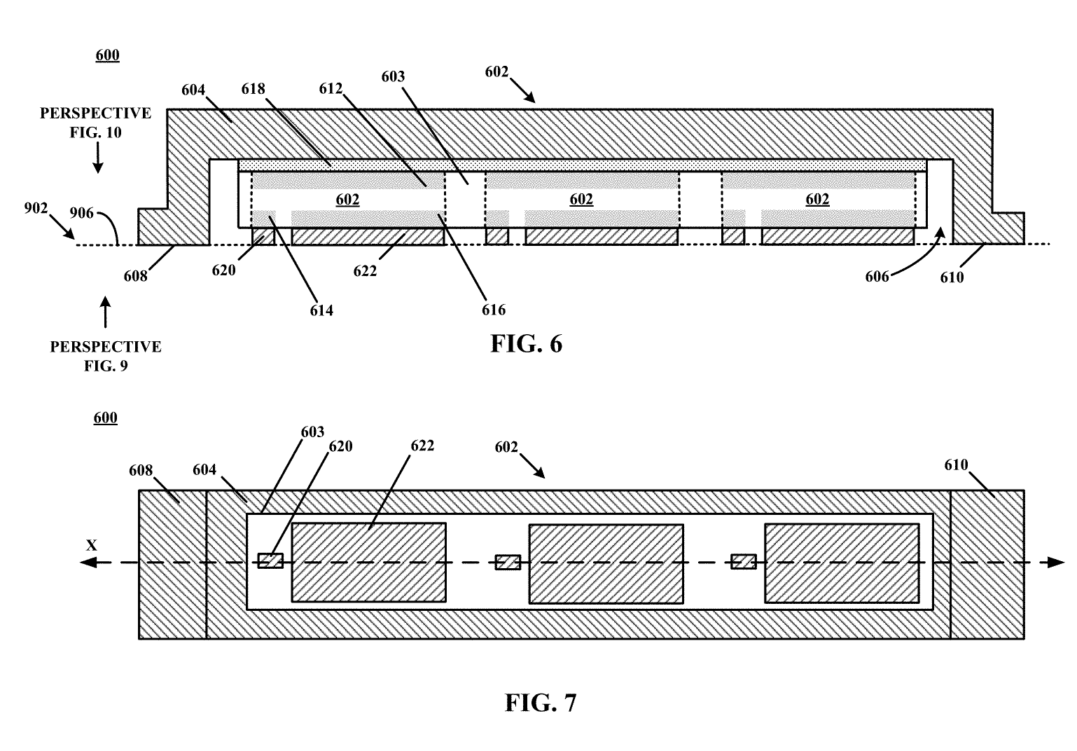

As mentioned above, more than a single instance of high-side transistor 108 may be integrated within or formed as first semiconductor die 200, and more than a single instance of low-side transistor 116 may be integrated within or formed as third semiconductor die 300. FIGS. 6-7 show a second common contact semiconductor device package 600 (hereinafter “package 600”) that comprises a number of distinct instances of semiconductor die 602 integrated within or formed as a single, common semiconductor die 603. In this example, semiconductor die 603 is coupled to a conductive clip 604 whereby, due to similarity in structural configuration of first semiconductor die 200 of FIG. 2 and second semiconductor die 300 of FIG. 3, semiconductor die 602 may correspond to either one of first semiconductor die 200 and second semiconductor die 300. Similarly, conductive clip 604 may correspond to either one of conductive clip 110 and conductive clip 118 of FIG. 1. By extension, package 600 of FIGS. 6-7 may correspond to either one of first package 102 and second package 104 of FIG. 1. Thus, the following discussion provided with reference to package 600 of FIGS. 6-7 is equivalently applicable to each one of package 102 and package 104 as shown in FIG. 1.

In particular, FIG. 6 shows a cross-sectional view of package 600 according to the disclosure, and FIG. 7 shows a bottom view of package 600 of FIG. 6. Example views of package 600 of FIGS. 6-7 mounted to a substrate 902 is illustrated in at least one of FIGS. 8-10. As mentioned above, package 600 comprises conductive clip 604. Conductive clip 604 includes a recess 606 (see FIG. 6) and is configured to mount to substrate 902 along a first surface 608 and a second surface 610 that bound recess 606. In this example, each one of three instances of semiconductor die 602, equivalently semiconductor die 603, illustrated solely to be consistent with the three-phase half-bridge circuit example of the present disclosure, is mounted within recess 606 in a same orientation such that a drain or source contact 612 is coupled to conductive clip 604, and such that a gate contact 614 and a source or drain contact 616 extend exposed within the recess 606 and along a same long axis X of conductive clip 604 (see FIG. 6). In some examples, although not required, a conductive adhesive 618 is in place between drain or source contact 612 and conductive clip 604. In some examples, although not required, a conductive contact 620 is in positioned to gate contact 614 and a conductive contact 622 is in positioned to source or drain contact 616 to facilitate a surface-mounting process whereby package 600 is mounted to substrate 902. Such an implementation as shown in FIGS. 6-7, whereby gate contact 614 and source or drain contact 616 extend exposed within the recess 606 and are aligned along long axis X of conductive clip 604 as shown in FIG. 6, advantageously facilitates precise registration with conductive traces or pads on a substrate (see FIGS. 8-10).

As mentioned above, example views of package 400 of FIGS. 4-5 mounted to substrate 802 is illustrated in at least one of FIGS. 8-10. Additionally, the discussion provided with reference to package 400 of FIGS. 4-5 is equivalently applicable to each one of first package 102 and second package 104 as shown in FIG. 1. FIG. 8 in particular shows a bottom view of half-bridge circuit 100 of FIG. 1 realized using package 400 of FIGS. 4-5, equivalently using first package 102 of FIG. 1 comprising high-side transistors 108A-C for high-side switching of half-bridge circuit 100, and using second package 104 of FIG. 1 comprising low-side transistors 116A-C for low-side switching of half-bridge circuit 100. FIG. 10 shows a top view of half-bridge circuit 100 of FIG. 8.

The “bottom view” perspective of FIG. 8, and the “top view” of FIG. 10, is as illustrated in FIG. 4, whereby in FIG. 8 and FIG. 10 an instance of first package 102, and an instance of second package 104, is shown mounted to substrate 802 to define half-bridge circuit 100 of FIG. 1. More specifically, and with collective reference to FIGS. 1, 4, 8 and 10, instance of first package 102 is mounted to substrate 802 such that each one of a first surface 408 and a second surface 410 of conductive clip 414 of first package 102 (see FIG. 4) is in contact with a corresponding one of first contact pads or traces 804A-B (collectively “traces 804”) that are deposited on a top surface 806 of substrate 802 (see FIG. 8). In this example, each one of first contact pads or traces 804A-B is in turn coupled to supply voltage node 112 (see FIG. 1 and FIG. 8). Similarly, instance of second package 104 is mounted to substrate 802 such that each one of a first surface 408 and a second surface 410 of conductive clip 414 of second package 104 is in contact with a corresponding one of second contact pads or traces 806A-B (collectively “traces 806”) that are deposited on top surface 806 of substrate 802. In this example, each one of second contact pads or traces 806A-B is in turn coupled to supply voltage node 112 (see FIG. 1 and FIG. 8). In this manner, conductive clip 414 (or equivalently “CAN 414”) may be utilized as a power supply node for half-bridge circuit 100.

Furthermore, first package 102 is mounted to substrate 802 such that each instance of conductive contact 420 of first package 102, that in turn is positioned to gate contact 414 of a corresponding instance of high-side transistor 108 (see FIG. 1; FIG. 4), is in contact with a corresponding instance of third contact pads or traces 808A-C (collectively “traces 808”) that are deposited on top surface 806 of substrate 802 (see FIG. 8). In this example, each one of third contact pads or traces 808A-C is in turn coupled to a corresponding one of high-side input nodes 124A-C (see FIG. 1). Similarly, second package 104 is mounted to substrate 802 such that each instance of conductive contact 420 of second package 104, that in turn is positioned to gate contact 414 of a corresponding instance of low-side transistor 116 (see FIG. 1; FIG. 4), is in contact with a corresponding instance of fourth contact pads or traces 810A-C (collectively “traces 810”) that are deposited on top surface 806 of substrate 802 (see FIG. 8). In this example, each one of fourth contact pads or traces 810A-C is in turn coupled to a corresponding one of low-side input nodes 126A-C (see FIG. 1).

Furthermore, first package 102 is mounted to substrate 802 such that each instance of conductive contact 422 of first package 102, that in turn is positioned to drain contact 106 of a corresponding instance of high-side transistor 108 (see FIG. 1; FIG. 4), is in contact with a corresponding instance of fifth contact pads or traces 812A-C that are deposited on top surface 806 of substrate 802 (see FIG. 8). Similarly, second package 104 is mounted to substrate 802 such that each instance of conductive contact 422 of second package 104, that in turn is positioned to source contact 114 of a corresponding instance of low-side transistor 116 (see FIG. 1; FIG. 4), is in contact with a corresponding instance of fifth contact pads or traces 812A-C (collectively “traces 812”) that are deposited on top surface 806 of substrate 802 (see FIG. 8). In this example, each one of fifth contact pads or traces 812A-C is in turn coupled to a corresponding one of switch nodes 122A-C (see FIG. 1). In this manner, a conductive trace or pad on substrate 802 may be utilized as a switch node for half-bridge circuit 100.

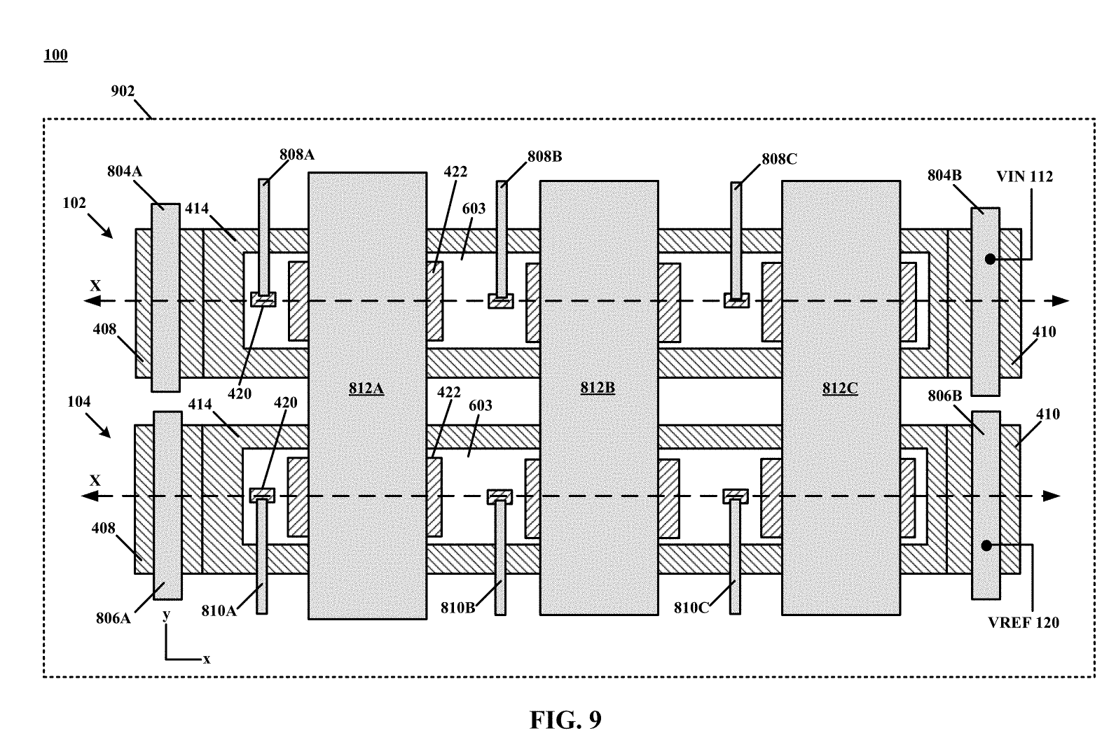

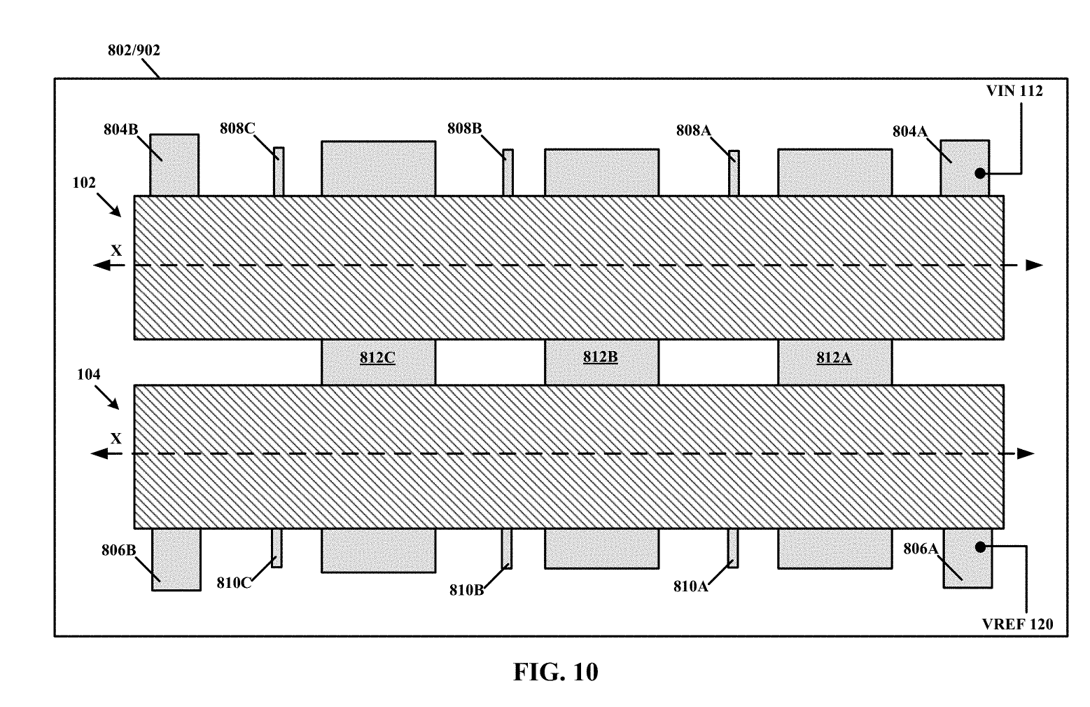

As mentioned above, example views of package 600 of FIGS. 6-7 mounted to substrate 902 is illustrated in at least one of FIGS. 8-10. Additionally, the discussion provided with reference to package 600 of FIGS. 6-7 is equivalently applicable to each one of first package 102 and second package 104 as shown in FIG. 1. FIG. 9 in particular shows a bottom view of half-bridge circuit 100 of FIG. 1 realized using package 600 of FIGS. 6-7, equivalently using first package 102 of FIG. 1 comprising high-side transistors 108A-C for high-side switching of half-bridge circuit 100, and using second package 104 of FIG. 1 comprising low-side transistors 116A-C for low-side switching of half-bridge circuit 100. FIG. 10 shows a top view of half-bridge circuit 100 of FIG. 9.

The “bottom view” perspective of FIG. 9, and the “top view” of FIG. 10, is as illustrated in FIG. 6, whereby in FIG. 9 and FIG. 10 an instance of first package 102, and an instance of second package 104, is shown mounted to substrate 902 to define half-bridge circuit 100 of FIG. 1. More specifically, and with collective reference to FIGS. 1, 6, 9 and 10, instance of first package 102 is mounted to substrate 902 such that each one of a first surface 408 and a second surface 410 of conductive clip 414 of first package 102 (see FIG. 6) is in contact with a corresponding one of first contact pads or traces 804A-B (collectively “traces 804”) that are deposited on a top surface 906 of substrate 902 (see FIG. 9). In this example, each one of first contact pads or traces 804A-B is in turn coupled to supply voltage node 112 (see FIG. 1 and FIG. 9). Similarly, instance of second package 104 is mounted to substrate 902 such that each one of a first surface 408 and a second surface 410 of conductive clip 414 of second package 104 is in contact with a corresponding one of second contact pads or traces 806A-B (collectively “traces 806”) that are deposited on top surface 906 of substrate 902. In this example, each one of second contact pads or traces 806A-B is in turn coupled to supply voltage node 112 (see FIG. 1 and FIG. 9). In this manner, conductive clip 414 (or equivalently “CAN 414”) may be utilized as a power supply node for half-bridge circuit 100.

Furthermore, first package 102 is mounted to substrate 902 such that each instance of conductive contact 420 of first package 102, that in turn is positioned to gate contact 414 of a corresponding instance of high-side transistor 108 (see FIG. 1; FIG. 6), is in contact with a corresponding instance of third contact pads or traces 808A-C (collectively “traces 808”) that are deposited on top surface 906 of substrate 902 (see FIG. 9). In this example, each one of third contact pads or traces 808A-C is in turn coupled to a corresponding one of high-side input nodes 124A-C (see FIG. 1). Similarly, second package 104 is mounted to substrate 902 such that each instance of conductive contact 420 of second package 104, that in turn is positioned to gate contact 414 of a corresponding instance of low-side transistor 116 (see FIG. 1; FIG. 6), is in contact with a corresponding instance of fourth contact pads or traces 810A-C (collectively “traces 810”) that are deposited on top surface 906 of substrate 902 (see FIG. 9). In this example, each one of fourth contact pads or traces 810A-C is in turn coupled to a corresponding one of low-side input nodes 126A-C (see FIG. 1).

Furthermore, first package 102 is mounted to substrate 902 such that each instance of conductive contact 422 of first package 102, that in turn is positioned to drain contact 106 of a corresponding instance of high-side transistor 108 (see FIG. 1; FIG. 6), is in contact with a corresponding instance of fifth contact pads or traces 812A-C that are deposited on top surface 906 of substrate 902 (see FIG. 9). Similarly, second package 104 is mounted to substrate 902 such that each instance of conductive contact 422 of second package 104, that in turn is positioned to source contact 114 of a corresponding instance of low-side transistor 108 (see FIG. 1; FIG. 6), is in contact with a corresponding instance of fifth contact pads or traces 812A-C (collectively “traces 812”) that are deposited on top surface 906 of substrate 902 (see FIG. 9). In this example, each one of fifth contact pads or traces 812A-C is in turn coupled to a corresponding one of switch nodes 122A-C (see FIG. 1). In this manner, a conductive trace or pad on substrate 902 may be utilized as a switch node for half-bridge circuit 100.

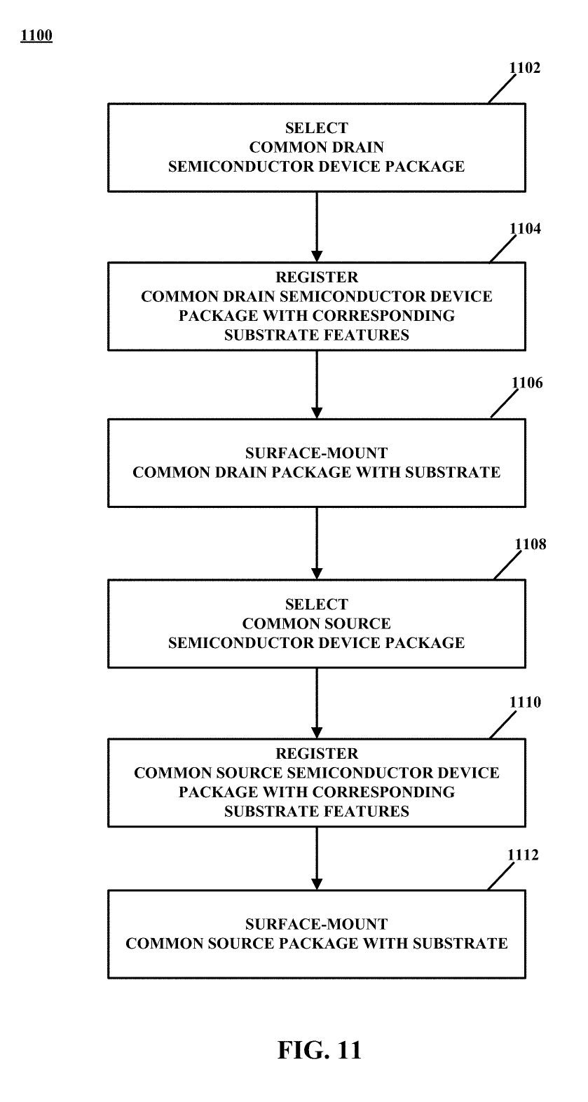

FIG. 11 shows an example method 1100 for defining half-bridge circuit 100 of FIG. 1 in accordance with the disclosure. The example method 1100 comprises the step of selecting (1102) a common drain semiconductor device package from among a set of common contact semiconductor device packages configured and/or arranged in accordance with the principles of the present disclosure. An example of such a common drain semiconductor device package is illustrated and discussed above in connection with FIGS. 1, 2 and 4-7. The example method 1100 further comprises the steps of aligning or registering (1104) the common drain semiconductor device package with corresponding features on a substrate, and subsequently surface-mounting (1106) the common drain semiconductor device package on the substrate. For example, with reference to FIG. 8, common drain semiconductor device package 102 may be aligned with one or both of traces 804A-B such that each one of first surface 408 and second surface 410 of conductive clip 414 is precisely centered on or along a corresponding one of traces 804A-B in both directions x and y. Advantageously, by doing so, each instance of conductive contact 420 and conductive contact 422 is by extension precisely aligned or registered with a corresponding one of traces 808 and traces 812. This is because, as mentioned above, gate contact 414 (as coupled to conductive contact 420) and drain contact 416 (as coupled to conductive contact 422) extend exposed within recess 406 and are aligned along long axis X of conductive clip 404 (see FIGS. 4-5). Common drain semiconductor device package 102 may then be swiftly surface-mounted to substrate 802 such that mechanical and electrical connections are established between traces 804, 808 and 812 and corresponding elements of common drain semiconductor device package 102.

The example method 1100 further comprises the step of selecting (1108) a common source semiconductor device package from among a set of common contact semiconductor device packages configured and/or arranged in accordance with the principles of the present disclosure. An example of such a common source semiconductor device package is illustrated and discussed above in connection with FIGS. 1, 3 and 4-7. The example method 1100 further comprises the steps of aligning or registering (1110) the common source semiconductor device package with corresponding features on a substrate, and subsequently surface-mounting (1112) the common source semiconductor device package on the substrate. For example, with reference to FIG. 9, common source semiconductor device package 104 may be aligned with one or both of traces 806A-B such that each one of first surface 408 and second surface 410 of conductive clip 414 is precisely centered on or along a corresponding one of traces 806A-B in both directions x and y. Advantageously, by doing so, each instance of conductive contact 420 and conductive contact 422 is by extension precisely aligned or registered with a corresponding one of traces 810 and traces 812. This is because, as mentioned above, gate contact 414 (as coupled to conductive contact 420) and drain contact 416 (as coupled to conductive contact 422) extend exposed within recess 406 and are aligned along long axis X of conductive clip 404 (see FIGS. 6-7). Common source semiconductor device package 104 may then be swiftly surface-mounted to substrate 802 such that mechanical and electrical connections are established between traces 806, 810 and 812 and corresponding elements of common source semiconductor device package 104.

The example method 110 represents a paradigm shift in that, when semiconductor device package 102, 104 is incorporated in a half-bridge circuit for example, conductive clip 110, 118 may be utilized as a power supply node for the half-bridge circuit whereas conductive trace or pad 812 on substrate 802, 902 may be utilized as a switch node for the half-bridge circuit. Additionally, a manufacturing-related benefit may be realized because the orientation of vertical channel transistors of first semiconductor die 200 or second semiconductor die 300 facilitates registration between semiconductor device package 102, 104 and substrate 802, 902 during a process to surface-mount semiconductor device package 102, 104 to substrate 802, 902. Additionally, a performance-related benefit may be realized because semiconductor device package 102, 104 itself does not degrade device level characteristics of vertical channel transistors of first semiconductor die 200 or second semiconductor die 300. This is because the switch node contacts of first semiconductor die 200 or second semiconductor die 300 are not series-connected with any extraneous or unnecessary packaging element of semiconductor device package 102, 104 itself (e.g., leadframe, bridging wire bond, conductive clip, etc.). Instead, the switch node contacts of are directly connected (or via contacts 422 or 622 in some examples) to pads or traces 812 on the substrate 802, 902.

Additionally, the following numbered examples demonstrate one or more aspects of the disclosure.

### EXAMPLE 1

A semiconductor device package comprising: a conductive clip that includes a recess and that is configured to mount to a substrate along a first surface and a second surface that bound the recess; and at least two vertical channel transistors that are of a same type, and that are mounted within the recess in a same orientation such that a drain or source contact is coupled to the conductive clip, and such that a gate contact and a source or drain contact extend exposed within the recess and along a same long axis of the conductive clip.

### EXAMPLE 2

The semiconductor device package of example 1, wherein the drain contact of each one of the at least two vertical channel transistors is electrically coupled to the conductive clip, and the gate contact and the source contact extend exposed within the recess and along the same long axis of the conductive clip.

### EXAMPLE 3

The semiconductor device package of any one of examples 1-2, wherein the source contact of each one of the at least two vertical channel transistors is electrically coupled to the clip, and the gate contact and the drain contact extend exposed within the recess and along the same long axis of the conductive clip.

### EXAMPLE 4

The semiconductor device package of any one of examples 1-3, wherein each one of the at least two vertical channel transistors is a distinct semiconductor die.

### EXAMPLE 5

The semiconductor device package of any one of examples 1-4, wherein the at least two vertical transistors are integrated within a common semiconductor die.

### EXAMPLE 6

A system comprising :a first semiconductor package that includes a first conductive clip and a first plurality of transistors, wherein: the first conductive clip includes a recess and is configured to mount to a substrate along a first surface and a second surface of the first conductive clip that bound the recess, and the first plurality of transistors include at least two vertical channel transistors that are of a same type, and that are mounted within the recess of the first conductive clip in a same orientation such that a drain contact is coupled to the first conductive clip, and such that a gate contact and a source contact extend exposed within the recess and along a same long axis of the first conductive clip; and a second semiconductor package that includes a second conductive clip and a second plurality of transistors, wherein: the second conductive clip includes a recess and is configured to mount to the substrate along a first surface and a second surface of the second conductive clip that bound the recess, and the second plurality of transistors include at least two vertical channel transistors that are of a same type, and that are mounted within the recess the second conductive clip in a same orientation such that a source contact is coupled to the second conductive clip, and such that a gate contact and a drain contact extend exposed within the recess and along a same long axis of the second conductive clip.

### EXAMPLE 7

The system of example 6, wherein each one of the first plurality of transistors is a distinct semiconductor die.

### EXAMPLE 8

The system of any one of examples 6-7, wherein the first plurality of transistors are integrated within a common semiconductor die.

### EXAMPLE 9

The system of any one of examples 6-8, wherein each one of the second plurality of transistors is a distinct semiconductor die.

### EXAMPLE 10

The system of any one of examples 6-9, wherein the second plurality of transistors are integrated within a common semiconductor die.

### EXAMPLE 11

The system of any one of examples 6-10, wherein each one of the first plurality of transistors is a vertical n-channel power transistor.

### EXAMPLE 12

The system of any one of examples 6-11, wherein each one of the first plurality of transistors is a vertical p-channel power transistor.

### EXAMPLE 13

The system of any one of examples 6-12, wherein each one of the second plurality of transistors is a vertical n-channel power transistor.

### EXAMPLE 14

The system of any one of examples 6-13, wherein each one of the second plurality of transistors is a vertical p-channel power transistor.

### EXAMPLE 15

The system of any one of examples 6-14, wherein each one of the first plurality of transistors is a vertical fin-based multi-gate transistor.

### EXAMPLE 16

The system of any one of examples 6-15, wherein each one of the second plurality of transistors is a vertical fin-based multi-gate transistor.

### EXAMPLE 17

The system of any one of examples 6-16, further comprising a printed circuit board, wherein the first semiconductor package and the second semiconductor package are mounted to the printed circuit board as part of a multi-phase bridge circuit.

### EXAMPLE 18

A method comprising: mounting at least two vertical channel transistors that are of a same type to a recess of a conductive clip, that is configured to mount to a substrate along a first surface and a second surface that bound the recess, in a same orientation such that a drain or source contact is coupled to the conductive clip, and such that a gate contact and a source or drain contact extend exposed within the recess and along a same long axis of the conductive clip.

### EXAMPLE 19

The method of claim 18, wherein the drain contact of each one of the at least two vertical channel transistors is electrically coupled to the conductive clip, and the gate contact and the source contact extend exposed within the recess and along the same long axis of the conductive clip, and the method further comprising: mounting the conductive clip to the substrate; and coupling the conductive clip to a ground reference node of half-bridge circuitry that is configured to drive a multi-phase motor.

### EXAMPLE 20

The method of any one of examples 19-20, wherein the source contact of each one of the at least two vertical channel transistors is electrically coupled to the conductive clip, and the gate contact and the drain contact extend exposed within the recess and along the same long axis of the conductive clip, and the method further comprising: mounting the conductive clip to the substrate; and coupling the conductive clip to a battery supply node of half-bridge circuitry that is configured to drive a multi-phase motor.

Various examples of the disclosure have been described. Any combination of the described systems, operations, or functions is contemplated. These and other examples are within the scope of the following claims.

1. A semiconductor device package comprising:
a conductive clip that includes a recess and that is configured to mount to a substrate along a first surface and a second surface that bound the recess; and
at least two vertical channel transistors that are of a same type, and that are mounted within the recess along a continuous surface and in a same orientation such that a drain or source contact is coupled to the conductive clip along the continuous surface, and such that a gate contact and a source or drain contact extend exposed within the recess and along a same long axis of the conductive clip.

2. The semiconductor device package of claim 1, wherein the drain contact of each one of the at least two vertical channel transistors is electrically coupled to the conductive clip, and the gate contact and the source contact extend exposed within the recess and along the same long axis of the conductive clip.

3. The semiconductor device package of claim 1, wherein the source contact of each one of the at least two vertical channel transistors is electrically coupled to the conductive clip, and the gate contact and the drain contact extend exposed within the recess and along the same long axis of the conductive clip.

4. The semiconductor device package of claim 1, wherein each one of the at least two vertical channel transistors is a distinct semiconductor die.

5. The semiconductor device package of claim 1, wherein the at least two vertical transistors are integrated within a common semiconductor die.

6. A system comprising:
a first semiconductor package that includes a first conductive clip and a first plurality of transistors, wherein:
the first conductive clip includes a recess and is configured to mount to a substrate along a first surface and a second surface of the first conductive clip that bound the recess, and
the first plurality of transistors include at least two vertical channel transistors that are of a same type, and that are mounted within the recess of the first conductive clip along a continuous surface and in a same orientation such that a drain contact is coupled to the first conductive clip along the continuous surface, and such that a gate contact and a source contact extend exposed within the recess and along a same long axis of the first conductive clip; and
a second semiconductor package that includes a second conductive clip and a second plurality of transistors, wherein:
the second conductive clip includes a recess and is configured to mount to the substrate along a first surface and a second surface of the second conductive clip that bound the recess, and
the second plurality of transistors include at least two vertical channel transistors that are of a same type, and that are mounted within the recess of the second conductive clip along a continuous surface and in a same orientation such that a source contact is coupled to the second conductive clip along the continuous surface, and such that a gate contact and a drain contact extend exposed within the recess and along a same long axis of the second conductive clip.

7. The system of claim 6, wherein each one of the first plurality of transistors is a distinct semiconductor die.

8. The system of claim 6, wherein the first plurality of transistors are integrated within a common semiconductor die.

9. The system of claim 6, wherein each one of the second plurality of transistors is a distinct semiconductor die.

10. The system of claim 6, wherein the second plurality of transistors are integrated within a common semiconductor die.

11. The system of claim 6, wherein each one of the first plurality of transistors is a vertical n-channel power transistor.

12. The system of claim 6, wherein each one of the first plurality of transistors is a vertical p-channel power transistor.

13. The system of claim 6, wherein each one of the second plurality of transistors is a vertical n-channel power transistor.

14. The system of claim 6, wherein each one of the second plurality of transistors is a vertical p-channel power transistor.

15. The system of claim 6, wherein each one of the first plurality of transistors is a vertical fin-based multi-gate transistor.

16. The system of claim 6, wherein each one of the second plurality of transistors is a vertical fin-based multi-gate transistor.

17. The system of claim 6, further comprising a printed circuit board, wherein the first semiconductor package and the second semiconductor package are mounted to the printed circuit board as part of a multi-phase bridge circuit.

18. A method comprising:
mounting at least two vertical channel transistors that are of a same type to a recess of a conductive clip, that is configured to mount to a substrate along a first surface and a second surface that bound the recess, in a same orientation such that a drain or source contact is coupled to the conductive clip, and such that a gate contact and a source or drain contact extend exposed within the recess and along a same long axis of the conductive clip.

19. The method of claim 18, wherein the drain contact of each one of the at least two vertical channel transistors is electrically coupled to the conductive clip, and the gate contact and the source contact extend exposed within the recess and along the same long axis of the conductive clip, and the method further comprising:
mounting the conductive clip to the substrate; and
coupling the conductive clip to a ground reference node of half-bridge circuitry that is configured to drive a multi-phase motor.

20. The method of claim 18, wherein the source contact of each one of the at least two vertical channel transistors is electrically coupled to the conductive clip, and the gate contact and the drain contact extend exposed within the recess and along the same long axis of the conductive clip, and the method further comprising:
mounting the conductive clip to the substrate; and
coupling the conductive clip to a battery supply node of half-bridge circuitry that is configured to drive a multi-phase motor.
